(19) United States
(12) Patent Application Publication
(10) Pub. No.: US 2005/0047962 A1
(43) Pub. Date: Mar. 3, 2005

(54) Ffe array dispenser

(75) Inventors: Thomas Laurell, Lund (SE); Johan Nilsson, Bjarred (SE); Gyorgy Marko-Varga, Malmo (SE)

Correspondence Address: LADAS & PARRY LLP, 224 SOUTH MICHIGAN AVENUE, SUITE 1200, CHICAGO, IL, 60604, US

(73) Assignee: Astrazeneca AB, 151 85 Sodertalje (SE)

(21) Appl. No.: 10/498,073

(22) PCT Filed: Dec. 11, 2002
(86) PCT No.: PCT/SE02/02281

(30) Foreign Application Priority Data
Dec. 11, 2001 (SE) 0104125-0
Jul. 15, 2002 (SE) 0202228-3
Aug. 13, 2002 (SE) 0202400-8

(51) Int. Cl. H02N 2/00; H01L 41/04; B01L 3/00

(52) U.S. Cl. 422/63; 222/504; 310/328; 422/100

(57) ABSTRACT

A dispensing device for use in chemical analysis comprising at least two dispenser nozzles, a chamber having at least two inlets, a membrane entity constituting part of defining elements of said chamber, said membrane entity comprising at least one flexible membrane, and an actuation element, such that liquids brought to flow through said inlets into said chamber can be pressurised by actuating the membrane entity by providing a pulse to said actuation element, and thereby dispensing an amount of liquid through each of said at least two nozzles. Embodiments include devices comprising integrated free flow electrophoresis separation means.

### FIELD OF INVENTION

The present invention relates to methods and devices for dispensing solutions. More specifically it relates to dispensing devices in a microscopic format for dispensing small amounts of solutions that are to be chemically analysed.

### BACKGROUND

The identification of new biological targets of medical relevance, aided by human genome research, is an expanding area of modern drug research. These targets may, for example, be receptors responsible for triggering particular responses in the body. While on one hand, attention has focussed on designing and synthesising potential drug molecules that may interact with these targets, and thus block, reduce or even enhance these responses, the task of identifying of the target proteins and target protein complexes themselves has also demanded attention and required improvements.

There is a need for methods allowing rapid and efficient identification of useful peptides, as well as for selecting and identifying relevant peptides, polypeptides and proteins present in a complex biological sample. Such methods exist, but many of these have proven to be slow and labour intensive. In addition, these methods do not make efficient use of the sample as they consume relatively large amounts of test material and are limited in their screening efficiency.

EP 0439327 discloses a control system for a micropump, meant for medical appplications and chemical analysis, comprising means for generating actuating pulses for a piezoelectric element for actuating the pump.

U.S. Pat. No. 6,280,148 discloses a microdosing device and method for operating same. Said device comprises a pressure chamber which is at least partly delimited by a displacer; an actuating device for actuating the displacer, the volume being adapted to be changed by actuating the displacer; a media reservoir which is in fluid communication with the pressure chamber via a first fluid line; an outlet opening which is in fluid communication with the pressure chamber via a second fluid line; a means for detecting the position of the displacer; and a control means which is connected to the actuating device and to the means for detecting the position of displacer, wherein the control means comprises means for controlling the actuating device with a signal of low edge steepness to cause the displacer to move from a first position to a predetermined second position defining a larger volume of the pressure chamber than said first position; and that the control means comprises means for controlling the actuating device with a signal of high edge steepness to cause a discharging of a defined volume of fluid from the outlet opening.

U.S. Pat. No. 6,296,811 discloses a fluid dispenser comprising a fluid chamber having two actuators coupled thereto. One of the actuators damps a fluid response of the other. The fluid chamber may comprise a cylindrical capillary, and the actuators may comprise spaced cylindrical piezoelectric elements.

DE 10010208 discloses a microdispensing device comprising an integrated arrangement formed in plates for dispensing droplets with a volume of e.g 10 nanolitre to 3 microlitre. The device is intended to be actuated using a pneumatic pressure pulse. Three cross sections measures are defmed for a first channel (large), an outlet bypass channel (smaller) and a second channel (smallest).

EP 0810438 discloses a microvolume liquid handling system which includes a microdispenser employing a piezoelectric transducer attached to a glass capillary, a positive displacement pump for priming and aspirating transfer liquid into the dispenser, controlling the pressure of the liquid system, and washing the microdispenser between liquid transfers, and a pressure sensor to measure the liquid system pressure and produce a corresponding electrical signal. The pressure signal is used to verify and quantify the microvolume of transfer liquid dispensed and is used to perform automated calibration and diagnostics on the microdispenser. Mass spectrometry involving ionization by matrix-assisted laser desorption (MALDI) has established itself as a standard procedure for the analysis of biosubstances with large molecules. For this purpose, time-of-flight mass spectrometers (TOF-MS) are usually employed, although Fourier transform ion cyclotron resonance spectrometers (FT-ICR) or radio frequency quadrupole ion trap mass spectrometers (in short: ion traps) have also been utilized.

In the following, the molecules of biosubstances to be studied will be referred to simply as “analyte molecules” or “biomolecules”. In all cases, analyte molecules are present either in very diluted form in aqueous solutions, pure or mixed with organic solvents. Sometimes these analytical solutions are very complex and dirty with respect to the requirements of the analytical procedures, e.g., in the case of body fluids.

The biosubstances include all biopolymers and sometimes other substances with large molecules such as corticosteroids. “Biopolymers” comprise oligonucleotides (i.e. fragments of genetic material in various forms such as DNA or RNA), polysaccharides and proteins (the essential building blocks of the living world) as well as their special analogues and conjugates such as glycoproteins or lipoproteins, and peptides arising from the action of digestive enzymes.

The selection of matrix substance for MALDI depends on the type of analyte molecule; more than a hundred different matrix substances are now known. One of the tasks of the matrix substances include isolating the analyte molecules from each other wherever possible and bind them to the sample carrier plate, to transfer the molecules into the vapor phase by forming a vapor cloud during the laser bombardment, and ultimately to ionize the biomolecules by protonation or deprotonation, i.e., to add or remove one or more protons. For this task it has proven useful to incorporate the analyte molecules individually in the crystals of the matrix substances during their crystallization, or at least to finely distribute them in the boundary areas between the crystals. Here it seems important to separate the analyte molecules from each other, i.e., no clusters of analyte molecules should be allowed in the prepared matrix crystal sample.

A variety of procedures are known for applying analytes and matrices. The simplest of these entails the pipetting of a solution containing both analyte and matrix onto a cleaned, metallic sample support. The drop of solution wets a certain area of the metal surface (or its oxide layer) whose size on hydrophilic surfaces is many times larger than that of the diameter of a drop. The size depends on the hydrophilicity and the microstructuring of the metal surface as well as on the properties of the droplet, in particular that of the solvent. After drying of the solution, a sample spot consisting of small matrix crystals forms that is the same size as that of the originally wetted surface area is formed. The matrix crystals are usually not uniformly distributed throughout the formerly wetted area. As a rule, crystals of the matrix start growing at the inner margin of the wetting surface on the metal plate. They then grow towards the interior of the wetting surface. They often form thin needle crystals, as is the case, for example, of the frequently used matrices 5-dihydroxybenzoic acid (DHB) or 3-hydroxypicolinic acid (HPA), which often stand out from the carrier plate at the interior of the spot. The center of the spot is frequently empty or covered with fine crystals, although often they cannot be used for MALDI ionization because of their high concentration of alkaline salts. The loading of the crystals with biomolecules is also very uneven. This type of loading therefore requires viewing of the sample carrier surface during MALDI ionization by a video microscope which can be found in any commercially available mass spectrometer used for this type of analysis. Ion yield and mass resolution vary in the sample spot from place to place. It is often an arduous process to find a suitable position on the sample spot with a satisfactory analyte ion yield and mass resolution, and only experience, trial and error allow for improvements.

Although there are control programs for mass spectrometers with algorithms for automatically seeking the best spots for MALDI-ionization, such procedures, involving many attempts and evaluations, are of necessity very slow.

With other loading procedures the matrix substance is already present on the carrier plate before application of the solvent droplets, which now only contain analyte molecules.

If the surface of the sample carrier plate is not hydrophilic, but hydrophobic, smaller crystal conglomerates are formed, but the droplets tend to wander in an uncontrollable manner during drying. Hence the localization of the crystal conglomerates cannot be predicted and must be sought during the MALDI process. Furthermore, there is a considerable risk that droplets will conglomerate and thus render a separate analysis of samples impossible.

Biosample analyses are now performed in their thousands, a situation which demands automatic high throughput procedures. A visual control or search, or even an automated search, would obstruct such a high throughput procedure.

Recent prior art includes a procedure which leads to local and size-defined crystallization fields on small hydrophilic anchor regions of 100 to 800 micrometer in diameter within an otherwise hydrophobic surface (DE 197 54 978 C2). The aqueous drops are fixed by the hydrophilic anchors and prevented from wandering even when they initially rest on surrounding lyophobic areas. During drying the droplets withdraw onto the anchor, and relatively dense, homogeneously distributed, crystalline conglomerates arise on the exact position of these anchors (sometimes even structured as a single compact crystalline block depending on the type and concentration of matrix substance). It could be shown that the detection limit for analyte molecules improves with reduction of the surface area of the wetting surface. Thus, smaller quantities of analytes and more diluted solutions can be worked with during sample preparation; such an advantage is expressed in better running biochemical preparatory procedures and reductions in chemical material costs. With a suitable preparation the analytical sensitivity over the surface of the sample is highly uniform. Thus the ionization process can be freed from the need to perform visual or automated searches for favorable sites; instead a “blind” bombardment of the crystal conglomerates with desorbing laser light can be used. This preparation method for prelocated spots of equal sensitivity accelerates the analytical process.

The crystal conglomerates forming on the hydrophilic anchor surfaces reveal a microcrystalline structure suitable for the MALDI-process. As the speed of the drying process is increased, the crystalline structure becomes finer.

Here a “hydrophobic” surface is understood as a water repellant surface, i.e. one resistant to wetting by aqueous solutions. Correspondingly, a “hydrophilic” surface is understood as one that can be easily wetted by water. “Oleophobic” and “oleophilic” (also referred to sometimes as “lipophobic” and “lipophilic”) refer to surfaces which repel or which can be wetted by oil, respectively. Organic solvents that are not miscible with water usually have an oily nature in this meaning of wettability, i.e. they can wet oleophilic faces. They are as a rule miscible with oil. Organic solvents that are miscible with water, e.g. methanol, acetone or acetonitrile, can wet both oleophilic and hydrophilic surfaces in a pure state. However, the wettability of oleophilic surfaces reduces as the water content increases.

An opinion that has persisted over a long period is that hydrophobic surfaces are always also oleophilic, and that oleophobic surfaces are always hydrophilic. However, for some years it has been known that surfaces exist which are both hydrophobic and oleophobic; these include smooth surfaces of perfluorinated hydrocarbons such as polytetrafluoroethylene (PTFE). Such surfaces are designated here as “lyophobic”, a term which has been adopted from colloidal science.

Recently, it has also become known that the wetting or liquid repelling character of a surface strongly depends on its microstructure. An example of this is the so called “lotus effect” (named after the lotus-plant).

A surface is particularly designated as “hydrophobic” when a drop retracts on a surface during drying or aspiration with a pipette, reducing the wetted surface reduces in size and leaving behind a dry surface (so called “dynamic hydrophobia”).

As a rule, biomolecules are best dissolved in water, sometimes with the addition of organic, water-soluble solvents such as alcohols, acetone or acetonitrile. The analytical solutions of biomolecules sometimes also contain other substances such as glycols, glue-like buffering agents, salts, acids or bases depending on their preparation. The MALDI process is disrupted considerably by the presence of these impurities, sometimes through prevention of protonation, and sometimes through the formation of adducts. In particular, alkali ions often form adducts with analyte molecules of varying size and prevent any precise mass determination. The concentration of alkali ions in the sample preparation, as well as the concentration of other impurity substances must be kept extremely low by careful purification procedures.

For purification and simultaneous enrichment of biomolecules one can use so-called affinity adsorption media similar to those used in affinity chromatography. While in affinity chromatography one uses highly bioselective affinity adsorbents, for the purification of initially unknown mixtures of biopolymers without losses of special types of biomolecules one needs non-specific adsorbents that can bind all biomolecular constituents of the mixture to as near a similar degree as possible.

For purification of peptides, proteins or DNA mixtures, sponge-like microspheres of adsorbent material (such as POROS, a registered trademark of Perseptive Biosystems, Inc.), pipette tips filled with sponge-like adsorbent (such as ZIPTIPs, a registered trademark of Millipore Corporation) or C18 coated magnetized spheres (such as GenoPure, a product of Bruker Daltonics, Inc.) have proven particularly useful until now. These materials are all strongly oleophilic and bind peptides or oligonucleotides via hydrophobic bonds. As a rule, biomolecules can be eluted using aqueous methanol or acetonitrile solutions, and elution can often be assisted by altering the pH-value. However, purification with these materials is labor-intensive since it requires additional materials and additional procedural steps. In order to increase the throughput of microdispensing systems parallel multiple channel devises are often used. Each channel is supplied with its own flow connections and actuation means. This results in a complex system for electrical interconnections to the different channels where a lot of wiring is necessary.

### SUMMARY

The present invention satisfies the above need for higher processing speeds. A specimen that has been separated into different fractions can be processed faster because the fractions can be processed in parallel. It is an object of the present invention to provide a device that can process, i.e. dispense, micro volumes of a large number of microfluidic fractions of a specimen simultaneously.

Another object of the present invention is to provide a device having a small internal volume, minimising priming times and supporting the use of small sample volumes.

Still another object is to provide a device with small internal surfaces minimising surface interaction with solutions to be dispensed. One of the believed seminal ideas/concepts originating from the inventors' insights is that of parallel laminar flow portions that do not mix, i.e., liquid portions containing different samples are arranged to flow parallel in separate laminar flows without any means for separating them other than the arranged small dimensions and arranged laminar flow in the microdomain. No walls, ducts or membranes are needed to separate said flow when the laminar flow once is established. In turn the reduced need for separating means makes it possible to reduce the dimensions of a dispenser further. This feature of parallel laminar flow portions that do not mix, clearly discerns the present invention from multiple dispensers according to known prior art.

An array dispenser can comprise a number of inlets, at least one pressure cavity with at least one dispenser nozzle, and a number of outlets different from said nozzles. The at least one pressure cavity is arranged in fluid connection with the outlets and the inlets. Each pressure cavity is also provided with a dispenser nozzle in fluid connection with said cavity, and a flexible membrane such that when the membrane is actuated by a force in a certain direction, the pressure in the cavity rises and an amount of liquid is dispensed through the dispenser nozzle.

It is a further object of the present invention to provide a device capable of dispensing droplets simultaneously or nearly simultaneously so that they will impact on certain predefined positions on e.g. a target plate suitable for subsequent analysis with e.g. a MALDI-TOF mass spectrometry equipment.

A number of parallel fractions comprising a length of fluid having a certain cross area that are arranged to enter the array dispenser can flow into said dispenser array without turbulence, i.e. with a laminar flow. Due to the arranged precise dimensions, a droplet of fluid dispensed from one nozzle in the array corresponds to a droplet dispensed from an other nozzle in the array, in that said droplets originate from corresponding positions in the above mentioned length of fluid.

Supply of fluid to be dispensed can be arranged by interfacing a number of parallel channels to the inlets of the dispenser (unit). At the time of dispensing, however, each pressure chamber, i.e., each pressure chamber membrane is actuated by one separate element generating the dispensation of droplets from at least two nozzles simultaneously.

Each separate flow (“wall-less” flow channel) may be supplied with its own actuating element e.g. opposing each nozzle in the pressure chamber. The liquids in the different “wall-less” flow channels may then be dispensed individually by arranging the distance between two adjacent nozzles to be adequately large, thereby avoiding the generation of droplets in other nozzles but the one corresponding to the actuated membrane. In another embodiment of this design the adjacent separate actuating elements are used to actively suppress the cross-talk to enable closer positioning of the different nozzles.

The outlet can comprise a common channel provided that the flows/liquid are not to be collected for further analysis or storage. If that is the case a mechanically separated outlet is included to guide of the liquids/flow portions.

Another embodiment provides means for handling so called protective flows, i.e. two flows are separated not by a membrane or wall but by a third flow of e.g. a buffer solution having adequate properties. Said protective flows are supplied in channels between the analyte carrying channels. These protective flow channels must not be provided with nozzles but actuating elements may be advantageous due to the previously mentioned cross-talk suppression.

Alternative embodiments comprise nozzle-provided devices of the commercially available ink jet type to provide the dispensing function, including the so called thermal drop on demand and piezoelectric drop on demand devices.

Another embodiment comprises a dispenser arranged and aligned with a target plate holder device, making it possible to dispense small volumes of sample in parallel to a target plate, making the samples on said plate particularly suited to subsequent analysis by mass spectrometry involving ionization by matrix-assisted laser desorption (MALDI), as already mentioned above.

The necessary flow for generating the laminar “wall-less” channels is generated by external or internal flow-control means. A minimum flow for maintaining the laminar flow is arranged by means of flow control means that may comprise a syringe pump.

An array dispenser according to one embodiment of the invention is preferably manufactured of two or three thin layers bonded together. Each layer has an etched pattern of channels, mainly being arranged in a surface portion and in the plane of the layer, and a number of cavities either mainly being arranged in a surface portion of a layer or extending throughout the thickness of the layer, forming a passage in a not yet assembled layer, enabling a liquid to pass e.g. from the outside of said dispenser into the channels and cavities inside of said dispenser.

### FIGURES

The invention is disclosed in the following description and described with the aid of the following figures in which:

FIG. 1a shows a dispenser having a single pressure cavity (pushbar portion removed for clarity)

FIG. 1b shows in cross section the nozzle portion of the dispenser array and the beneath arranged target plate,

FIG. 1c shows a detail of a dispenser from above containing parts of a dispenser array,

FIG. 1d and 1e show cross sections of the dispenser array in FIG. 1c,

FIG. 1f shows a detailed cross section of the nozzle and pushbar portion of the dispenser in FIG. 1a

FIG. 2 shows a dispenser having multiple pressure cavities

FIG. 3 shows a cross sectional view from the side a dispenser an a dockable extractor chip.

FIG. 4a and b shows two alternative embodiments of dispenser inlets/outlets.

FIG. 5 shows a dispenser with integrated separation function

FIG. 6 shows a free flow dispenser with integrated separation function

### DETAILED DESCRIPTION OF EMBODIMENTS OF THE INVENTION

Definitions

In the context of the present application and invention the following definitions apply:

The term “biomacromolecules” refers to molecules that can be found in the context of biological cells and that has a molecular weight typically greater than five kDa

The abbreviaton MALDI should be interpreted as matrix assisted laser desorption/ionisation

The term “MALDI target plate” is intended to designate a piece of material intended for carrying samples to be analysed by MALDI mass spectrometry.

The term “protein capturing biomacromolecule printing” refers to the act of depositing (“printing”) protein capturing molecules, e.g., antibodies, onto MALDI target plate positions.

The term “activate” refers to the act bringing something from a state of inactivity to a state of activity, e.g bringing surface molecules from a state where they do not capture protein molecules to a state where they do.

The term “protein chip target plate” refers to a MALDI target plate deposited with or intended to be deposited with protein samples.

The term “biomarker” refers to a specific biochemical in the body which has a particular molecular feature that makes it useful for measuring the progress of disease or the effects of treatment.

The abbreviation “FFE” should be interpreted free flow electrophoresis.

The term “virtual flow channel” is intended to mean a microscopic flowing portion of a laminary flowing fluid, said portion having a long axis being parallel to the direction of flow, and said portion having a width and a depth orthogonally to the direction of flow, said portion can be regarded as an entity not mixing with the rest of the flowing fluid because of said laminar flow and small (micro) dimensions, thus constituting a “virtual channel”. Alternative term: “virtual channel flow”, “virtual flow line” and “virtual flow lane”.

The inventive concept of the present invention resides in an array dispenser device in an environment of other specimen processing devices or portions of devices. The inventive concept is disclosed in the following description using a description of such an environment.

Dispenser

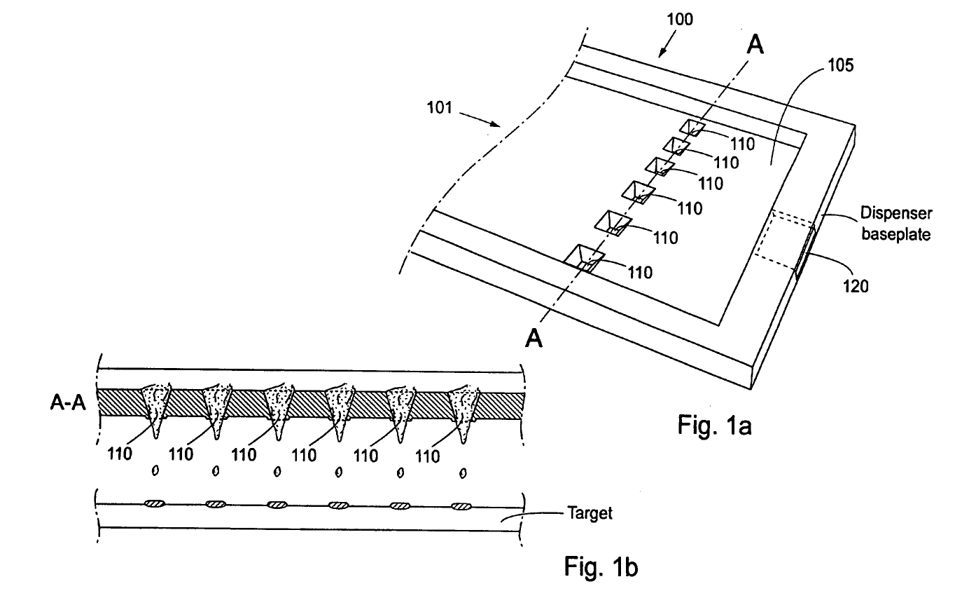

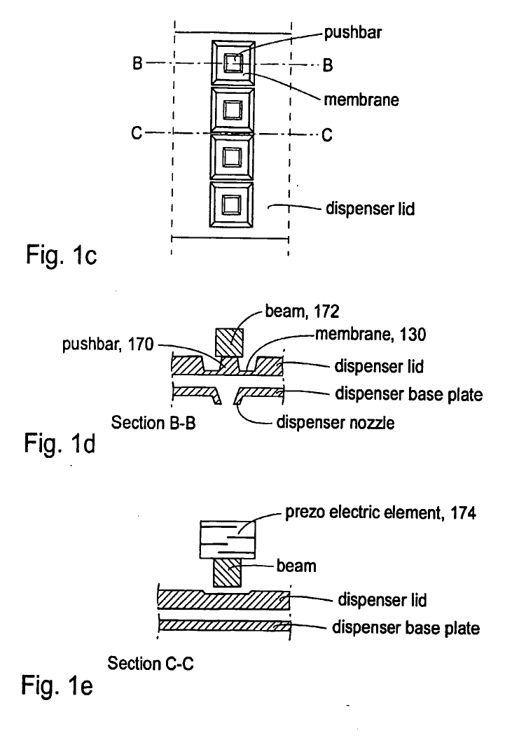

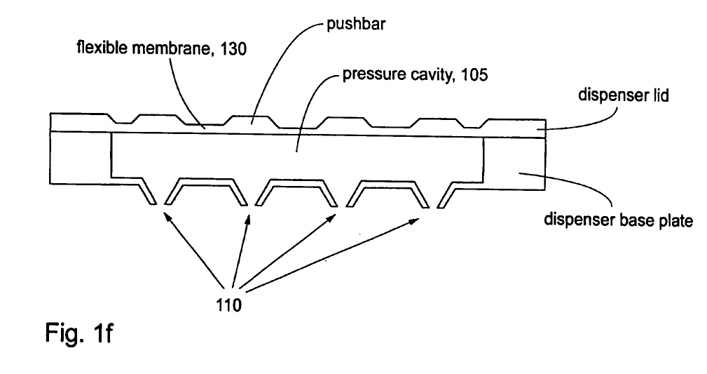

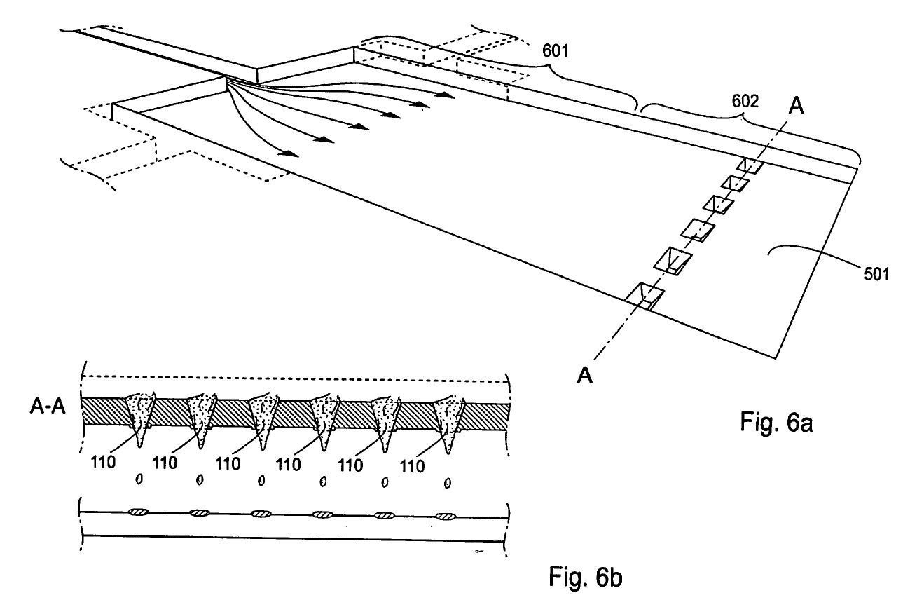

Referring to FIG. 1a, an array 100 according to a first embodiment of the present invention comprise one inlet 101 having a rectangular cross section, one pressure cavity 105 having a number of dispenser nozzles 110, said pressure cavity 105 being arranged in fluid communication with said inlet 101. Said pressure cavity 105 also being provided with an outlet 120, different from said nozzles, also arranged in fluid communication with said pressure cavity 105. Said outlet having a rectangular cross section. Each dispenser nozzle 110 is arranged in fluid connection with said cavity 105, and a flexible membrane 130 (FIG. 1c) is arranged as a defining surface of said pressure chamber/cavity 105, such that when the membrane 130 is actuated by a force in a certain direction, the pressure in the cavity rises and an amount of liquid is dispensed through the dispenser nozzle. This embodiment has the advantage that there is no need for separating walls, separating possible parallelly flowing different fractions of fluid near the dispenser nozzles, as indicated in FIG. 6. Components/fractions are held separated in different laminar flow portions of the flowing liquid due to the small dimensions, the arranged speed of flow, and due to a design that promotes laminar flow. Diffusion is kept to a minimum because of the relative short time period/length which the liquid has to flow when not guided by separation walls/surfaces.

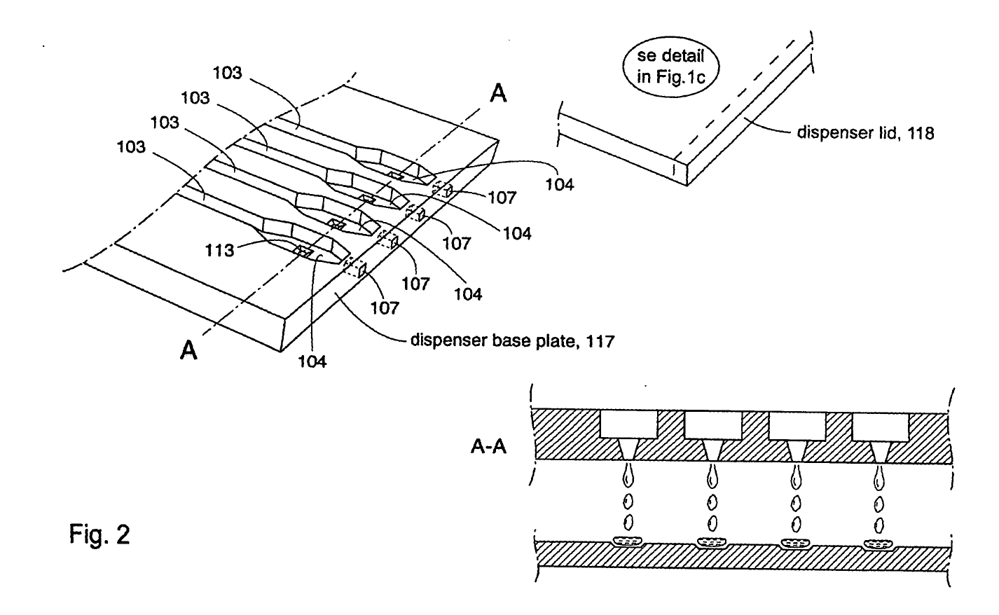

Referring to FIG. 2, an array dispenser according to a second embodiment of the present invention comprise a number of inlets 103, a number of pressure cavities 104 each having a dispenser nozzle 113, each of said pressure cavities being arranged in fluid communication with a corresponding inlet 103. Said pressure cavity 104 also being provided with an outlet 107, different from said nozzle, also arranged in fluid communication with said pressure cavity 104. Said outlet having a rectangular cross section. Each dispenser nozzle 113 is arranged in fluid connection with said corresponding cavity 104, and a flexible membrane 130 is arranged as a defining surface of said pressure chamber 104, such that a liquid can be supplied via the inlets 103 and dispensed through the dispenser nozzles 113, when the membrane 130 is actuated by a force in a certain direction, thereby forcefully rising the pressure in the cavity 104 such that an amount of liquid is dispensed. The outlets 107 provides the dispenser with flow-through means such that the inlets, cavities and outlets can be easily washed between e.g dispensing operations involving two different sets of fluids.

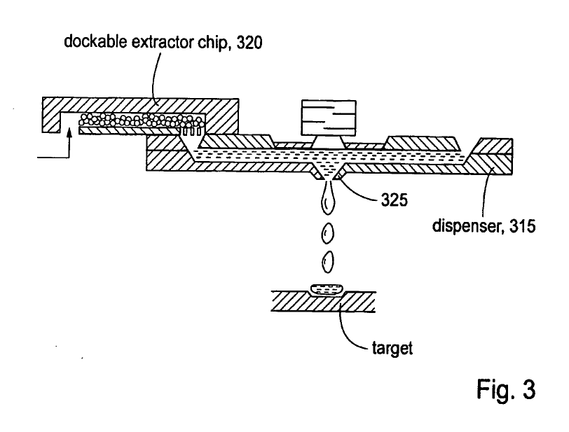

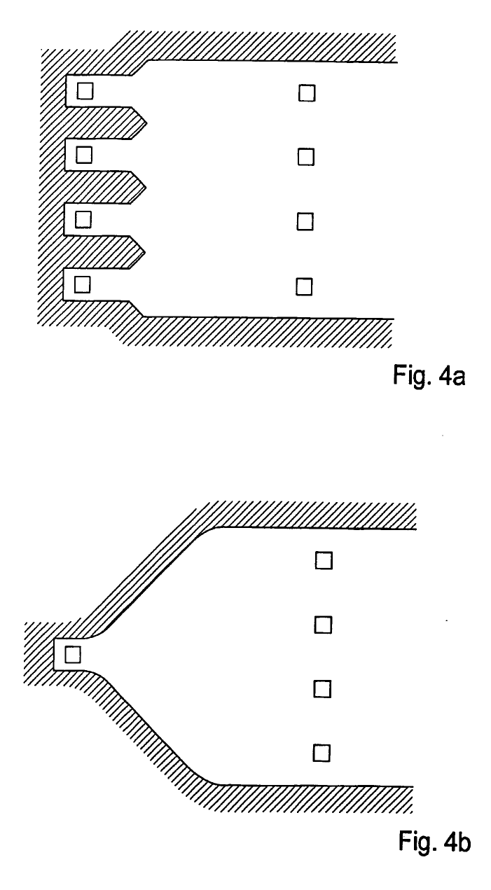

Referring to FIG. 3, in a third embodiment of the present invention an array dispenser 315 is arranged in close relationship to an extraction device 320 or an extraction portion of a combined device such that a flow of eluate from the extraction portion is conducted to a corresponding dispenser nozzle 325. A number of said nozzles 325 being arranged beside each other forming a dispenser nozzle array, in a similar way as described above in the first and second embodiments.

In a fourth embodiment, referring to FIG. 6, the dispenser comprises an integrated unit 600 comprising a free flow electrophoresis section 601 and a free flow dispenser section 602.

Actuation Force Distribution

A dispenser array according to an embodiment of the invention preferrably is built up from two plates, a base plate and a lid plate bonded together. The dispenser nozzle array comprises a chamber 501, see FIG. 6, in the base plate, having at least one inlet and at least two dispenser nozzles, and a membrane entity in the lid comprising at least one flexible membrane, and at least one pushbar 170 connected via a beam 172 to a single piezoelectric element 174 capable of providing an actuation force for actuating the membrane entity, and thereby dispensing droplets of liquid through said at least two nozzles simultaneously.

In another embodiment of the invention each pushbar is connected to an individual actuation element fascilitating individual actuation of each pushbar. In yet another embodiment of the invention a single pushbar supplied with a single actuation element without the beam is used for generating droplets from the nozzles simultaneously.

Single End/flow Through Embodiments

The dispenser may be supplied with one or more outlets facilitating fraction collection after the dispenser if not all of the sample volume is dispensed through the nozzles. For separate fraction collection from the different channels the outlet portion of the dispenser may be supplied with separating walls after the chamber.

Diagonal/other Arrangement

The nozzles must not necessarily be placed next to each other along a line perpendicular to the flow. The nozzles may be placed arbitrarily over the chamber surface as long each nozzle is still addressing the same flow line.

Target Plate Dispensing

Referring to FIG. 1 and 2, a dispenser nozzle array according to another preferred embodiment of the invention is arranged to dispense microscopic amounts of said each separate flow of eluate to a MALDI target plate having an array of spots or wells, i.e. a number of rows of wells in e.g. a 8×12 (,16×24, or higher order well plate. A control unit (not shown) that synchronises the action with the flow of mixture and flow of eluant controls the action of the dispenser. The stepwise movement of the well plate for a next row of wells to be placed in front (under) the dispenser array is also synchronised with the actions of the dispenser array.

The dispensing of droplets from the separate eluates is conducted in symphony with the evaporation of the eluant so that the amount of proteins deposited in the well can be increased over time by dispensing more droplets in the same well.

The well may be provided with enzymes that, because of the small dimensions, controlled temperature and the high concentration of proteins, digest said proteins and form a high concentration of peptides.

A high concentration of peptide is favourable when performing a further chemical analysis by means of e.g. mass spectrometry.

Enrichment Device

Another embodiment comprises an enrichment device having a dispensing device as described above, a target plate as described above having a number of target surfaces, and a control unit for delivering actuation pulses in a controlled manner to the piezoelectric element, such that precise amounts of liquid is deposited on the target surfaces at controlled points/intervals in time, allowing fluid to evaporate thereby enriching/increasing the concentration of sample molecules on said target surfaces.

Integrated Devices

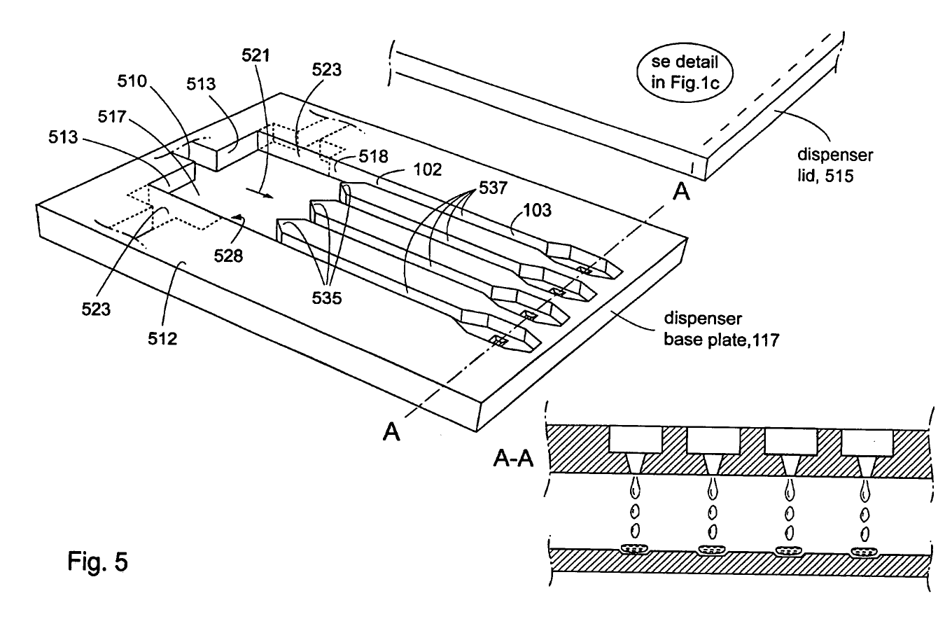

FIG. 5 shows a device suitable for performing integrated sequential separation and enrichment operations on a mixture of protein molecules

Dispenser with Integrated Separation Function

FIG. 5 and 6 shows a dispenser with integrated separation function. A solution to be separated and dispensed, e.g., an aqueous mixture of proteins to be analysed, is entered through an inlet opening 510 to a separation cavity 512 defined by walls 513, 518, a bottom surface 517 an a lid surface (not shown). Two of said walls are arranged having wall surfaces 518 parallel to the main flow direction 521. Part of said walls 518 comprises electrodes 523 for applying an electric field across the flow, such that when a mixture of the solution and a buffer/carrier ampholyte is arranged to flow through said separation cavity 517 a pH gradient is established and proteins in the solution is made to migrate towards their respective isoelectric points, as in the method of isoelectric focussing, known to those skilled in the art. The separated flows, the so-called virtual flow channels or flow lanes are then separated into real channels 537 by dividers 535. The flow then continues to the dispenser/dispenser section.

In an alternative embodiment, referring to FIGS. 5 and 6, the dividers 535 is omitted and the virtual flow channels continue directly to the dispenser/dispenser section.

In still alternative embodiment the channels 537 is provided with micro extraction means, e.g. a bed of microbeads for extracting analyte proteins from the solution. Said proteins is eluated by feeding an eluant through the channels, resulting in enriched and purified analytes entering the dispenser.

Operations Possible to Perform using the Dispenser

Protein-capturing biomacromolecule printing whereby series of capturing proteins such as antibodies are deposited onto MALDI taget plate positions.
Sample enrichment onto the activated capture surfaces of the protein chip target plate
Array format of sample deposition onto dedicated chip Target plates that can be used for a given assay in e. g. biomarker screening purposes. The type of target chip size, surface and geometry will be adjusted to the specific read out of the assay technology used, such as fluorescent, chemiluminescent optical imaging and detection units.
   Method of Operation

In one embodiment of the present invention the array dispenser will be operated by a non-interfaced solution, such that sample introduction is performed by depositing a droplet onto a droplet area arranged at the inlet side of the array dispenser. Next, the capillary forces of the array template will fill up the inlet nozzle chamber of the array without any need for capillary connections and micro-plumbing devices needed.

Material

The device is preferably manufactured in silicon. Silicon is essentially inert when dealing with protein mixtures at room or near-room temperature. The material is also very suitable for micro-machining techniques, e.g. for etching away parts of the material with established etching techniques.

Another advantage is that with said etching techniques the dimensions becomes very precise and it is possible to etch surface with far better than micrometer precision.

1. A dispensing device for use in chemical analysis comprising at least two dispenser nozzles, a chamber having at least two inlets, a membrane entity constituting part of the defining elements of said chamber, comprising at least one flexible membrane, and an actuation element, such that liquids brought to flow through said inlets into said chamber can be pressurised by actuating the membrane entity by providing an electric pulse to said actuation element, and thereby dispensing an amount of liquid through each of said at least two nozzles.

2. A dispensing device according to claim 1, where said membrane entity comprises a number of flexible membranes, one membrane for each at least two inlets, said membranes being divided by stiff areas of said membrane entity, said membranes being arranged beside each other such that the centre of each membrane and the centre of each dispenser nozzle is aligned.

3. A dispensing device according to claim 2, where each membrane has a pushbar with its centre arranged at the membrane centre, and each pushbar is mechanically connected to the single actuation element such that an actuation of the element causes all the membranes to flex simultaneously.

4. A dispensing device according to claim 3, where the connection between the pushbars and the actuation element is achieved by connecting means comprising a beam.

5. A dispensing device for dispensing sample amounts of a solution, characterised in that said device comprises at least two dispenser nozzles arranged in a plate beside each other on a line, said plate also comprising an inlet, a cavity comprising two electrodes for separation on molecular charge e.g. by isoelectric focusing, and a solid phase microextraction portion such that a solution fed at the inlet is partitioned into at least two partitions as it flows through said cavity, and such that each partition is directed into a separate conduit of said solid phase microextraction portion of said dispensing device and such that sample molecules caught by said solid phase surface auxiliary molecules can be eluted with an eluting solution and fed separately to each of said at least two dispenser nozzles.

6. An enrichment device comprising a dispensing device according to claim 1, a target plate having a number of target surfaces, and a control unit for delivering actuation pulses in a controlled manner to the piezoelectric element, such that precise amounts of liquid is deposited on the target surfaces at controlled points/intervals in time, allowing fluid to evaporate.

7. The device as recited in any of the preceding claims, where said actuation element is a piezoelectric element.
